(19) United States
(12) Patent Application Publication
(10) Pub. No.: US 2026/0099658 A1
(43) Pub. Date: Apr. 9, 2026

(54) TOP-DOWN BLACK-BOXED PHYSICAL DESIGN OF A CIRCUIT

(71) Applicant: Arm Limited, Cambridge (GB)

(72) Inventors: Markus Edward Malema, Trondheim (NO); Akshay Vijayashekar, Trondheim (NO)

(21) Appl. No.: 18/909,528

(22) Filed: Oct. 8, 2024

(51) Int. Cl. G06F 30/398

(52) U.S. Cl. CPC G06F 30/398

(57) ABSTRACT

A computer-implemented method for generating a physical design of a circuit supporting a top-down black-boxed approach, includes: receiving a file indicating a set of components of a circuit design, wherein at least one component of the set of components of the circuit design is a black-box component; for each of the at least one component of the set of components that is a black-box component, assigning a boundary shape and layout area to that component; initiating at least one simulation for evaluating a physical design metric; updating a feature of at least one of the at least one component of the set of components that is the black-box component based on the at least one simulation for evaluating the physical design metric; and initiating the at least one simulation for evaluating the physical design metric for the circuit design having the updated feature.

### BACKGROUND

In general, the basic pre-manufacturing design flow of a circuit includes creating a specification and architectural design (e.g., a high-level system specification), generating a register-transfer-level (RTL) design based on the specification and architectural design, performing logic synthesis (e.g., converting RTL design to netlist/gate-level design), and generating a physical design (e.g., converting netlist/gate-level design to layout form with placement and routing). The physical implementation stage often includes partitioning (breaking up of a circuit into subcircuits or modules that can each be designed or analyzed individually), floorplanning (determining shapes and arrangement of subcircuits and determining locations of external ports and other blocks), power planning (power and ground net distribution), placement of cell within blocks, clock network synthesis (for skew and delay requirements), routing, and timing optimization.

Typically, a bottom-up design flow is applied as part of a conventional tape-out oriented physical design flow to achieve a particular high-level design such that the subcircuits of a circuit design are designed first and then combined. For example, the full design may be split into various subcircuits that are handled by different design teams and then combined into the full design. Certain black-boxing tools exist which can be used by a designer as part of the design flow such that a subset of the full circuit that is of interest to the designer can be evaluated without the complement sub-design/subcircuits. In the current paradigm, in addition to the timing of when physical implementation stage processes are carried out, when using black-boxing tools, a physical design is created for every sub-design of the complement, resulting in several physical designs for the user.

Accordingly, it would be beneficial to have a tool that can improve the design flow and speed up the design process.

### BRIEF SUMMARY

Systems and techniques for a top-down black-box physical design of a circuit are provided. A top-down approach generally involves advancing from the high-level design to more detailed phases. By following a top-down approach, it is possible to make impactful design choice decisions earlier in the project life cycle. In addition, it is possible to model a subset of design through the creation of a single physical design.

In some aspects, the techniques described herein relate to a computer-implemented method for generating a physical design of a circuit, including: receiving a file indicating a set of components of a circuit design, wherein at least one component of the set of components of the circuit design is a black-box component; for each of the at least one component of the set of components that is a black-box component, assigning a boundary shape and layout area to that component; initiating at least one simulation for evaluating a physical design metric; updating a feature of at least one of the at least one component of the set of components that is the black-box component based on the at least one simulation for evaluating the physical design metric; and initiating the at least one simulation for evaluating the physical design metric for the circuit design having the updated feature.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1 illustrates a representational diagram depicting stages of design of a circuit using an EDA tool.

FIG. 2 illustrates a method for generating a physical design of a circuit.

FIG. 3 illustrates a conceptual diagram of a set of components of a circuit design.

FIGS. 4A-4C illustrate conceptual diagrams of a set of components of a circuit design that include black-box components.

FIGS. 5A-5F show conceptual diagrams of a process flow for various example top-down black-box physical designs of a circuit based on methods for generating a physical design of a circuit as described herein.

FIG. 6 illustrates a schematic diagram illustrating components of a computing device.

### DETAILED DESCRIPTION

Systems and techniques for a top-down black-box physical design of a circuit are provided. A top-down approach generally involves advancing from the high-level design to more detailed phases. By following a top-down approach, it is possible to make impactful design choice decisions earlier in the project life cycle. In addition, it is possible to model a subset of design through the creation of a single physical design.

From a conventional tape-out oriented physical design flow, every part of the design typically has a complete physical representation for the tape-out. Thus, a bottom-up flow is readily used in the conventional tape-out flow. As such, the design is physically implemented prior to the creation of a “black-box” for covering or replacing design instances with an empty design instance in the conventional tape-out oriented physical design flow. Instead of waiting for the physical design for performing black-boxed simulations, systems with tools for a top-down black-box physical design flow are presented.

The described techniques can be implemented by an electronic design automation (EDA) tool that assists in the design, implementation, verification, and subsequent manufacturing of semiconductor devices that include circuitry.

Electronic circuits can be designed in software using hardware description languages such as Verilog. The hardware description language allows a user to create a formal description of the electronic circuit, e.g., an RTL (register-transfer-level) design, that can be synthesized and simulated prior to the production of actual hardware such as an integrated circuit. The hardware description language forms a part of the EDA tool used for creating circuits such as complex digital circuits that can include application specific integrated circuits (ASICs) and programmable logic devices (e.g., field-programmable gate arrays (FPGAs)).

EDA tools incorporate and/or use models to provide simulated prototyping of electronic circuits. In this manner, functional operations and physical design metrics can be evaluated before tape-out (where the final file format of the circuit is generated for sending to a fabrication facility).

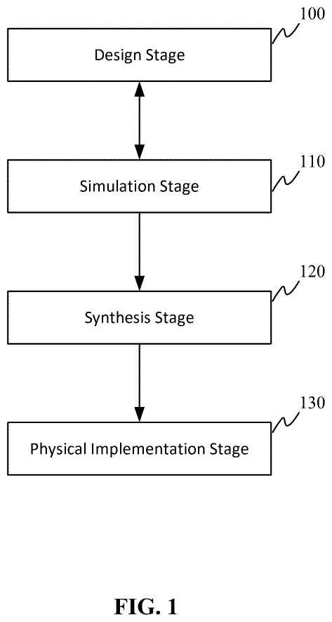

FIG. 1 illustrates a representational diagram depicting stages of design of a circuit using an EDA tool. Referring to FIG. 1, in a design stage 100, a designer designs the circuit which can be first designed as a schematic providing a graphical representation of the circuit, showing components and interconnections of the circuit and transformed into an RTL description creating a source design of the circuit. The RTL description can be represented in a hardware description language (e.g., VHDL or Verilog) which can then be further refined to precisely represent the circuit, specifying data flow and operations of the systems. A simulation stage 110 allows the designer to simulate and verify the operation of the source design of the circuit. The design and simulation stage can be iterative until a final design is achieved. In a synthesis stage 120, the RTL source design is transformed into a gate level representation, such as a gate level netlist, that describes the connectivity of the circuit. The netlist includes instances which represent logic blocks comprising gates connected between terminals by intermediate nets, e.g., wires. In the synthesis stage 120, a mathematical method is performed to verify the correctness of the RTL source design. During the synthesis stage 120, optimizations can be performed on the source design e.g., the logic blocks, for better performance of the circuit, for example through estimating routing and power connections. Lastly, a physical layout (e.g., place and route) of the optimized RTL source design of the circuit can be created in a physical implementation stage 130. For the described top-down approach for physical design of a circuit, it is possible to work within the physical implementation stage 130 with an incomplete—or subset of the complete circuit before advancing to a more refined design and performing the stages again. In addition, it is possible to explore potential physical designs without having the underlying circuit fully realized.

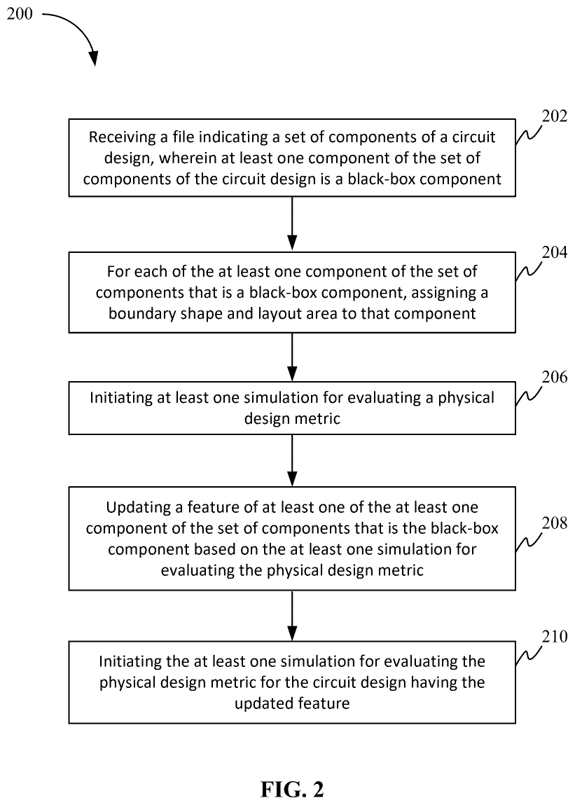

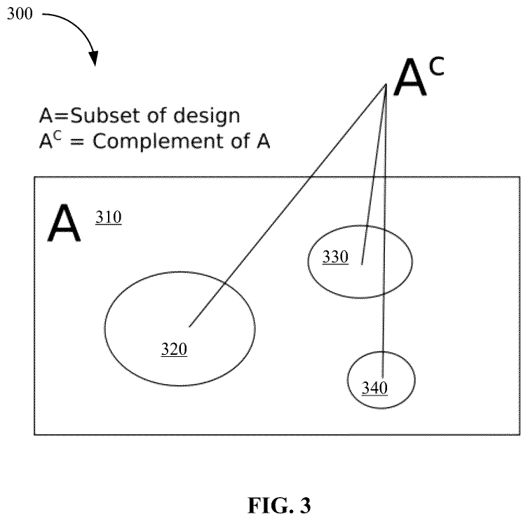

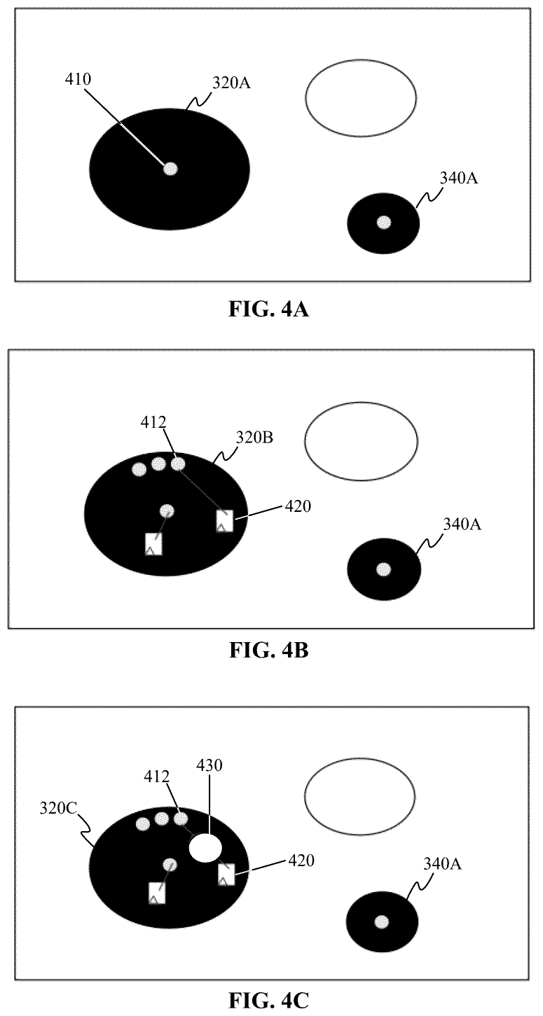

FIG. 2 illustrates a method for generating a physical design of a circuit. Referring to FIG. 2, method 200 includes receiving (202) a file indicating a set of components of a circuit design, wherein at least one component of the set of components of the circuit design is a black-box component. FIG. 3 illustrates a conceptual diagram of a set of components of a circuit design. As illustrated in FIG. 3, a set of components 300 of a circuit design can include a subset A 310 of a design and the complement of A (A^{c}), which can include one or more complement components, for example, complement components 320, 330, and 340. As will be described in more detail with respect to FIGS. 4A-4C, a subset of the complement components can be a black-box component (e.g., complement components 320 and 340 are shown as black-box components 320A, 320B, 320C, and 340A).

A black-box component is an empty design instance. In some cases, the empty design instance is a piece of code or module that is intended to implement a certain functionality and/or include other modules implementing certain functionalities. The empty design instance can be instantiated with a name/label, but not include any variable declarations, dataflow statements, functions, tasks, or lower module instances. In some cases, connection nodes, for example an optional list of ports (e.g., the inputs and outputs to the module), may be included (or “declared”) as part of the empty design instance. Thus, a black-box component is an empty design instance that may include some connection nodes. In some cases, some additional elements may be included, for example, registers may be included and even some logic may be included (but not the full functionality). In this manner, the design instance is considered empty because it does not have all of the definitions implementing the behavioral characteristics that are to be converted into a circuit (e.g., gate-level netlist) during synthesis.

In some cases, the set of components of the circuit design includes a subset of the circuit design containing fewer than all components of the circuit design. For example, the entire circuit design may be for a system on a chip and the file contains a subset of the circuit design directed to circuitry for the memory.

In some cases, all the components of the circuit design in the file are black-box components. Such a scenario can be used for exploratory evaluation of a physical design. Of course, exploratory evaluation of a physical design is possible for even a single black-box component.

The received (202) file indicating the set of components of the circuit design can be an RTL file. In some cases, the method can include converting the file into a netlist. For example, when the received file is an RTL file, the method can include performing synthesis to convert the RTL file into a netlist. Since the RTL file includes one or more black-box components, the netlist file would not include the specific circuitry of the black-box components, but instead includes a reference to the black-box component. In addition, in the cases where connection nodes are included with the black-box component, the netlist file includes connections to/from the black-box component.

In an alternative implementation, the received (202) file indicating the set of components of the circuit design can be a netlist file and the described processes may begin from receipt of the netlist file.

Returning to method 200, for each of the at least one component of the set of components that is a black-box component, method 200 includes assigning (204) a boundary shape and layout area to that component. There may be multiple black-box components for a design or only one black-box component. Each black-box component can be assigned its corresponding shape and layout area. The shape can be rectangular, irregular, or other geometry. The layout area refers to the size of the shape (and of course is dependent on the geometry of the boundary shape). In some cases, the boundary shape and layout area are defined by coordinates. In some cases, the placement location of the black-box component with respect to the other components can be part of the coordinate information indicating the boundary shape and layout area. In some cases, the placement location of the black-box component is a separate feature.

The assigned boundary shape and layout area can be based on one or more characteristics of that component, the one or more characteristics identified from a label for the component, any user input related to the component, and any elements included with the component.

In various implementations, the assigned boundary shape and layout area may be based on a predicted shape based on the one or more characteristics of that component, are a default assigned shape and area, or a randomly assigned shape and area. In some cases, up to all three options may be available.

In some cases, when basing the assigned boundary shape and layout area on one or more characteristics of the component as identified from the label for the component, the one or more characteristics identified from the label for the component is obtained from one or more prior designs of that component of the circuit design, from a specification for the component that may or may not have been designed yet, or from a default set being used to represent a generic component. For example, the label of the black-box component may be related to a graphics processing unit (GPU). In such a case, the system performing method 200 may use information from previous GPU designs to select a starting boundary shape and layout area for that black-box component. In some cases, a default boundary shape and layout area may be applied for that black-box component based on the label.

As another example, to support using user input related to the component in determining an assigned boundary shape and layout area, a user interface to a tool incorporating the method 200 can include an input field, selection tool, or other input mechanism providing a way for user input regarding the black-box component to be input to the system performing method 200. In some cases, user input may be available through a description within the black-box component. The description may be specific for a boundary shape and layout area.

In some cases, elements may be included with the black-box component that can be used by the system to determine the boundary shape and layout area to be assigned. For example, at least one element is included with the component, wherein the at least one element is selected from the group consisting of a communication node, register, and logic. Then, if certain connection nodes, registers, and/or logic are included in the black-box component, those elements can be used to by system to determine what type of component the black-box component may be describing. Various machine learning methods may be applied to assist with classifying a black-box component and/or determining an initial estimate for boundary shape and layout area.

Returning to FIG. 2, method 200 further includes initiating (206) at least one simulation for evaluating a physical design metric; updating (208) a feature of at least one of the at least one component of the set of components that is the black-box component based on the at least one simulation for evaluating the physical design metric; and initiating (210) the at least one simulation for evaluating the physical design metric for the circuit design having the updated feature.

The at least one simulation for evaluating the physical design metric (e.g., operations performed as part of steps 206 and 210) can include any simulations for evaluating a physical design metric including timing, area, dynamic power/energy, static power/energy, placement density, routing congestion, or a combination thereof.

In various implementations, the feature of a black-box component that is updated (208) based on results of a simulation for evaluation a physical design metric can be any attribute or property that is directly or indirectly related to a parameter of the manufactured device (sometimes referred to as “in silicon” or “silicon” for semiconductor devices that are fabricated in silicon/using a silicon wafer). That is, the described feature may be anything that could have an effect on any other physical design metric. This may be layout, geometry, cell type, and any other thing that may be able to be adjusted within the tool that can affect the physical design metric.

For example, updating (208) a feature of at least one of the at least one component of the set of components that is the black-box component based on the at least one simulation for evaluating the physical design metric can include, but is not limited to, updating a placement location of the component on a floorplan of the circuit design; adjusting the boundary shape of the component; adjusting the layout area of the component; updating placement of connection nodes assigned to the component; restricting or reducing permissions with respect to placement of logic inside the boundary shape of the component for placement operations; restricting or reducing permissions with respect to placement of logic inside the boundary shape of the component for routing operations; restricting or reducing permissions with respect to routing resources above the layout area of the component; or a combination thereof.

In a case where the received file indicating the set of components of the circuit design is a netlist file, as one implementation, changes to the black-box component may be carried out by “punching-in” elements to the file. As another implementation, changes to the black-box component are carried out in a separate tool (e.g., for modifying an RTL file and performing synthesis) and a new netlist file is received.

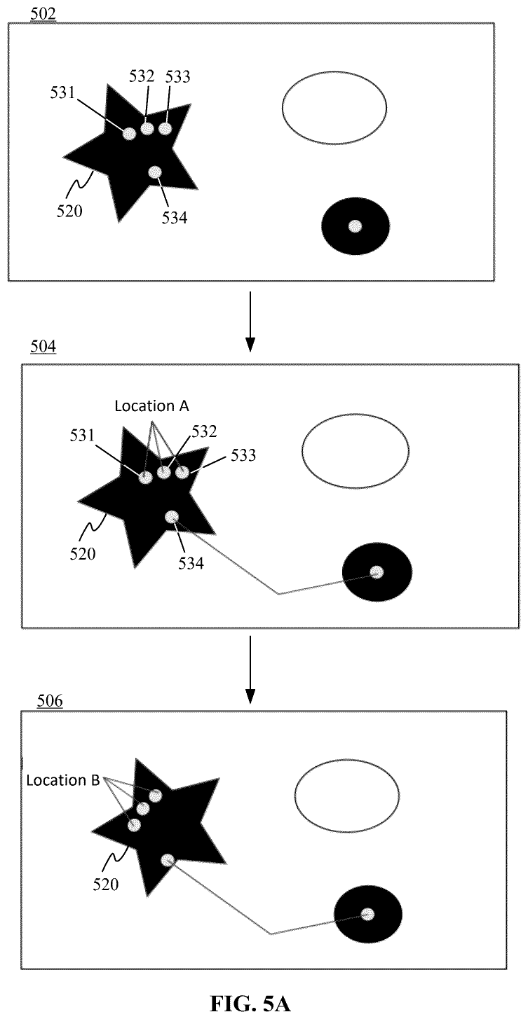

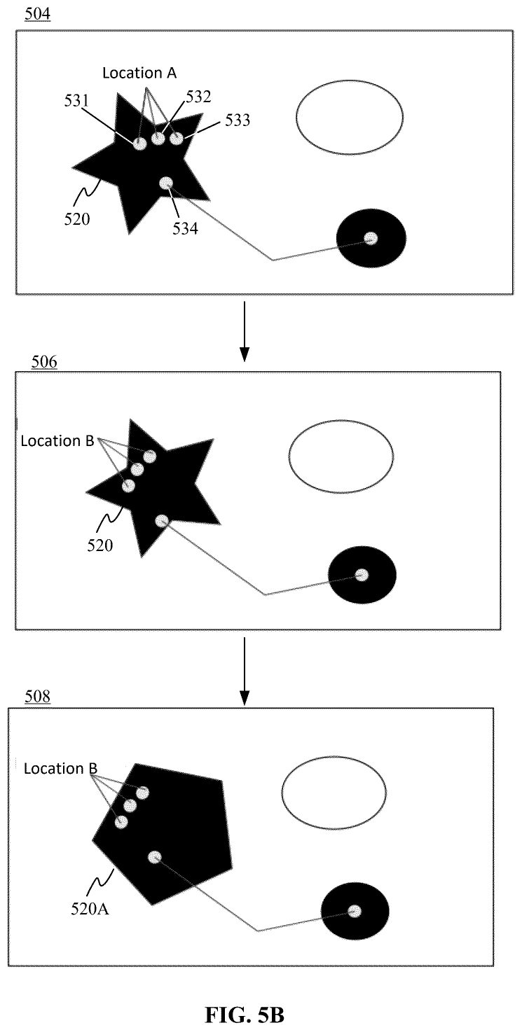

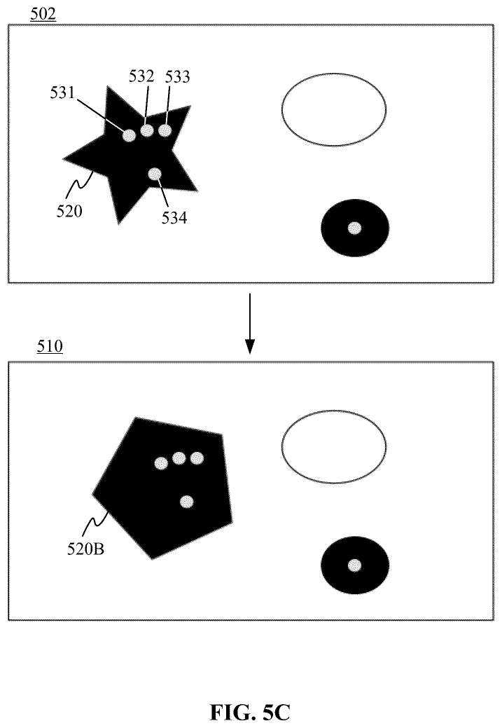

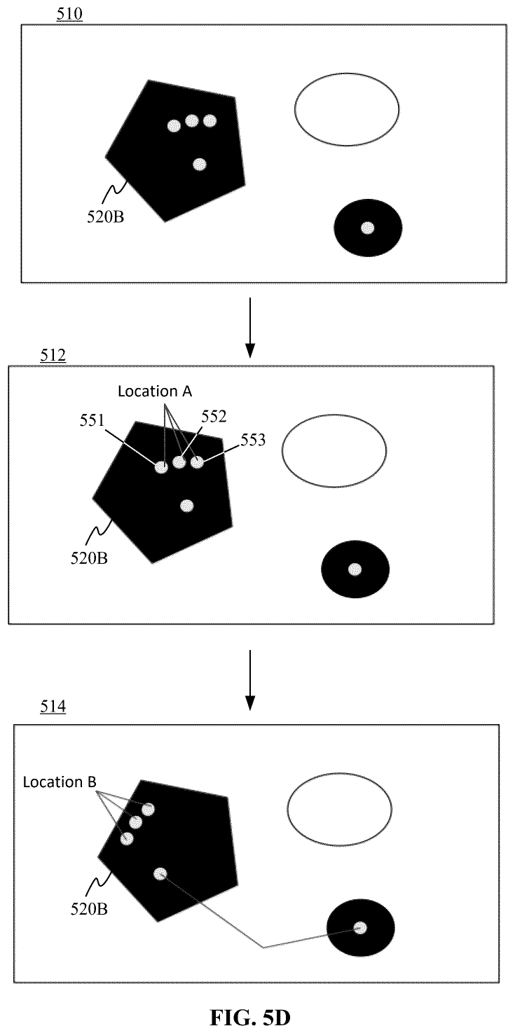

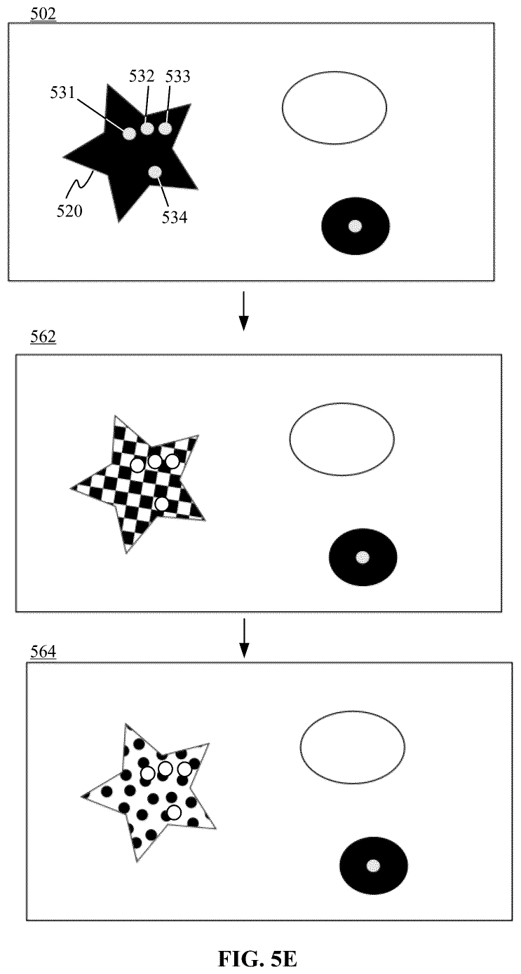

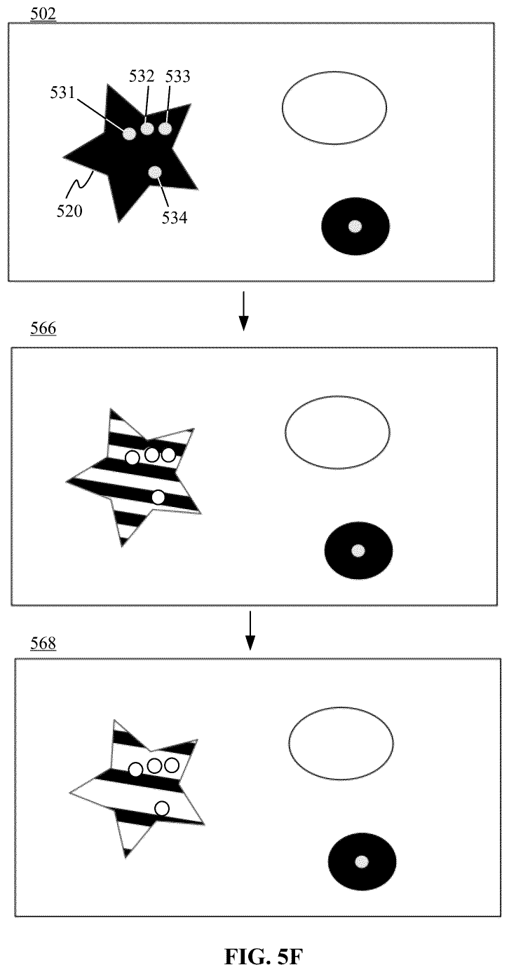

FIGS. 4A-4C illustrate conceptual diagrams of a set of components of a circuit design that include black-box components; and FIGS. 5A-5F show conceptual diagrams of a process flow for various example top-down black-box physical designs of a circuit based on methods for generating a physical design of a circuit as described herein.

The conceptual diagrams shown in FIGS. 4A-4C can represent components described in an RTL file. Such an RTL file may be received by a system performing method 200 as described with respect to FIG. 2. In some cases, a component of the set of components can have a dependency on an interface of a black-box component of the set of components. For example, a component of subset A (e.g., as shown in FIG. 3) can have a signal path to a black-box component (e.g., such as 320A of FIG. 4A).

Referring to FIG. 4A, a set of components of a circuit design 400 includes black-box components 320A and 340A. The black-box components may be completely empty or may include one or more connection nodes defined as part of the component, for example, connection node 410 of black-box component 320A. As will be apparent with reference to FIG. 5A, not all connection nodes that may be included/defined as part of a black-box component are required to be placed as part of placement/floorplanning operations.

Referring to FIG. 4B, in some cases, a black-box component (e.g., as instance 320B) can further include a register 420 coupled to a connection node 412.

Referring to FIG. 4C, in some cases, a black-box component (e.g., as instance 320C) can further include a logic gate 430 coupled to the register 420. In some cases, a logic gate can be included without a register.

Inclusion of the logic/registers in the black-box components can occur before synthesis of a file by the synthesis tool or user. Connection nodes for internal logic (e.g., to logic/registers) can be inserted/included after synthesis from the logic insertion; whereas connection nodes to/from external modules may be part of the file before synthesis. In a similar manner, insertion of one or more connection nodes to a black-box component can, in some cases, be carried out after the system receives the file in step 202 of FIG. 2.

Referring to the sequence of FIG. 5A, for a black-box component of the set of components of the circuit design in the file received such as described at step 202 of FIG. 2, the black-box component includes one or more connection nodes. For example, black-box component 520 includes four connection nodes 531, 532, 533, 534 (e.g., defined in the file). As shown in the first panel 502, the boundary shape and layout area for black-box component 520 is assigned as described at step 204 of FIG. 2. Then, as shown in the second panel 504, for the black-box component 520 of the set of components having the one or more connection nodes, at least one of the one or more connection nodes is assigned to a location at a boundary of that component or to a location within the layout area of that component after assigning the boundary shape and layout area for that component. Not all connections nodes that may have been defined as part of the black-box component are required to be placed. In some cases, fewer than all connection nodes are placed. This may occur, for example, where there are connections available, but are not intended to be used/connected to other components in the circuit design. For example, connection nodes 531, 532, 533 are shown as being placed while connection node 534 is indicated as not placed.

Referring to the third panel 506, after initiating at least one simulation (e.g., step 206 of FIG. 2), the placement of connection nodes (e.g., connection nodes 531, 532, 533) assigned to the black-box component 520 are updated (e.g., step 208 of FIG. 2) from a location A shown in the second panel 504 to a location B shown in the third panel 506. This change in placement may be based on the result of the simulation with respect to a desired physical design metric. In some cases, placement location(s) for the changed location is random. In some cases, the placement location(s) for the changed location is determined based on some metric or predefined adjustment pattern. In some cases, the placement location(s) for the changed location is based on prediction/learned placement models.

FIG. 5B illustrates an extension of the sequence of FIG. 5A that may occur as a result of simulations for evaluating a physical design metric. For example, following the operations described with respect to the second panel 504 and the third panel 506, at least one simulation for evaluating the physical design metric for the circuit design having the updated feature is carried out such as described with respect to step 210 of FIG. 2. Based on the result of the simulation, updating the same or different feature as updated in the third panel 506 may be carried out. As shown in the fourth panel 508, a boundary shape (and optionally layout area) of black-box component 520 is updated as black-box component 520A. Here, the connection node placement locations (e.g., at location B) remain the same as for the original boundary shape. However, embodiments are not limited thereto. As with placement of connection nodes, adjustments to boundary shape and/or layout area may be random, determined based on some metric or predefined adjustment pattern, based on prediction/learned placement models, etc.

FIG. 5C illustrates an alternate sequence from the first panel 502, in which no connection nodes are placed before initiating at least one simulation for evaluating a physical design metric. Here, after the boundary shape and layout area for black-box component 520 shown in the first panel 502 is assigned as described at step 204 of FIG. 2, at least one simulation for evaluating a physical design metric is initiated (e.g., as described at step 206 of FIG. 2) and the step (e.g., step 208 of FIG. 2) of updating a feature of the black-box component 520 includes adjusting the boundary shape of the component (and optionally adjusting the layout area) as shown by the black-box component 520B in the fifth panel 510.

FIG. 5D illustrates a scenario for an extension of the sequence of FIG. 5C. For example, following the operations described with respect to the fifth panel 510, one or more connection nodes (e.g., connection nodes 551, 552, 553) are assigned to a location at a boundary of that component or to a location within the layout area of that component after assigning the boundary shape and layout area for that component, as shown in the sixth panel 512. Here, the connection nodes may have been included in the black-box component 520B or inserted into the black-box component 520B at a later stage. Then, at least one simulation for evaluating the physical design metric for the circuit design having the placed connection nodes is carried out.

Referring to the seventh panel 514, after initiating at least one simulation (e.g., step 210 of FIG. 2), the placement of connection nodes (e.g., connection nodes 551, 552, 553) assigned to the black-box component 520B are updated (e.g., step 208 of FIG. 2) from a location A shown in the sixth panel 512 to a location B shown in the seventh panel 514. This change in placement may be based on the result of the simulation with respect to a desired physical design metric. In some cases, placement location(s) for the changed location is random. In some cases, the placement location(s) for the changed location is determined based on some metric or predefined adjustment pattern. In some cases, the placement location(s) for the changed location is based on prediction/learned placement models.

FIGS. 5E and 5F illustrate some additional scenarios of features that can be updated and physical design metrics that can be evaluated as part of the described method for generating a physical design of a circuit.

Referring to FIG. 5E, starting with the state as described with respect to the first panel 502, the boundary shape and layout area for black-box component 520 is assigned as described at step 204 of FIG. 2. Depending on implementation, connection nodes (e.g., connection nodes 531, 532, 533, 534) may or may not be assigned locations before performing simulations evaluating certain physical design metrics. In the scenario shown in FIG. 5E, as shown in the eighth panel 562, after performing step 206, a first restriction/reduction of placement of logic inside a placed shape boundary can be made (e.g., step 208 of FIG. 2) with respect to black-box component 520, which is represented by the first pattern in the black-box component 520. The restriction can be for placement operations (e.g., with respect to logic from other components that may be distributed across a floorplan outside of a specific region for the component), for routing operations (e.g., for signals routed in lower-level layers, including on an active/transistor layer), or for a combination of placement and routing.

Then, at least one simulation for evaluating the physical design metric for the circuit design having the updated feature is carried out such as described with respect to step 210 of FIG. 2. Based on the result of the simulation, updating the same or different feature as updated in the eighth panel 562 may be carried out. As shown in the ninth panel 564, an update to the restriction or reduction of placement of logic inside the placed shape boundary can be made (e.g., as described with respect to step 208), which is represented by the second pattern in the black-box component 520. It should be noted that the restriction/reduction of permissions to place logic may be for a region within a subset of the shape boundary and different portions of the area may have different permissions.

FIG. 5F shows a similar scenario as that described with respect to FIG. 5E; however, instead of restricting or reducing permissions to place logic inside the shape boundary, the scenario of FIG. 5F (and reflected in the tenth panel 566 and eleventh panel 568) involves restricting or reducing permissions with respect to routing resources above the layout area of the component. That is, after the first round of simulations in which updating the feature involves restricting permissions with respect to routing resources above the layout area of the component 520 is carried out and a second round of simulations are carried out, an update of the restriction or reduction of routing resource above the layout area of the component 520 can be made, as reflected by the change of pattern in component 520 between the tenth panel 566 and the eleventh panel 568. As with the scenario of FIG. 5E, the restricted area can be for a region within a subset of the area above the layout area and different portions of the area may have different permissions.

It should be understood that the illustrated examples are merely representative of potential functionality of an EDA tool and corresponding graphic user interfaces. In addition, different mechanisms for accessing and implementing method 200 may be provided, along with different interfaces and visual cues. For example, a stand-alone tool may also be provided.

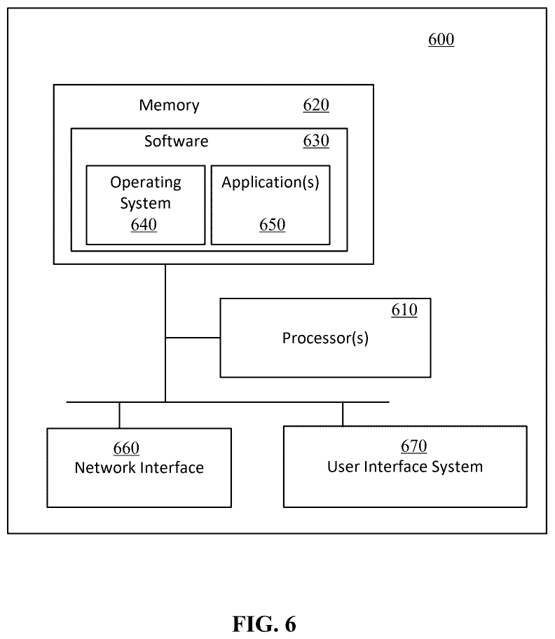

FIG. 6 illustrates a schematic diagram illustrating components of a computing device that may be used in certain implementations described herein. The computing device can be representative of a computing device on which an EDA tool runs as well as the methods for generating a physical design of a circuit as described herein. Referring to FIG. 6, computing device 600 (or “computing system”) can represent a personal computer, a mobile device, a tablet, a laptop computer, a desktop computer, a server, or a smart television as some examples. Accordingly, more or fewer elements described with respect to computing device 600 may be incorporated to implement a particular computing device.

Referring to FIG. 6, computing device 600 can include at least one processor 610, a memory 620, software 630 that includes operating system 640 and application 650 stored in the memory 620, network interface 660, and user interface 670. Processor 610 processes data and performs operations according to instructions of software 630. The instructions of application 650 may be loaded into computing device 600 and run on or in association with the operating system 640. Application 650 can include the methods as described (e.g., method 200), an EDA tool, or both (e.g., the methods integrated into the EDA tool, a plug-in and the EDA tool, separate applications, etc.). Memory 620 may comprise any computer readable storage media readable by processor 610 and capable of storing software 630 including application 650. Memory 620 (and any computer readable storage media forming memory 620 and/or accessible by computing device 600) does not consist of propagating signals nor is considered transitory media.

Computing device 600 can further include a user interface 670, which may include input/output (I/O) devices and components that enable communication between a user and the computing device 600 such as, but not limited to, a display, keyboard, mouse, microphone, and speakers. Computing device 600 may also include a network interface 660 that allows the system to communicate with other computing devices, including server computing devices and other client devices, over a network. Network interface 660 can include wired and/or wireless interfaces of one or more communication protocols and/or ports (e.g., for Wi-Fi or Ethernet, BLUETOOTH, near field communication (NFC), etc.).

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

What is claimed is:

1. A computer-implemented method for generating a physical design of a circuit, comprising:
receiving a file indicating a set of components of a circuit design, wherein at least one component of the set of components of the circuit design is a black-box component;
for each of the at least one component of the set of components that is a black-box component, assigning a boundary shape and layout area to that component;
initiating at least one simulation for evaluating a physical design metric;
updating a feature of at least one of the at least one component of the set of components that is the black-box component based on the at least one simulation for evaluating the physical design metric; and
initiating the at least one simulation for evaluating the physical design metric for the circuit design having the updated feature.

2. The method of claim 1, wherein updating the feature of the at least one of the at least one component of the set of components that is the black-box component based on the at least one simulation for evaluating the physical design metric comprises:
updating a placement location of the component on a floorplan of the circuit design;
adjusting the boundary shape of the component;
adjusting the layout area of the component;
updating placement of connection nodes assigned to the component;
restricting or reducing permissions with respect to placement of logic inside the boundary shape of the component for placement operations;
restricting or reducing permissions with respect to placement of logic inside the boundary shape of the component for routing operations;
restricting or reducing permissions with respect to routing resources above the layout area of the component; or
a combination thereof.

3. The method of claim 1, wherein the assigned boundary shape and layout area is based on one or more characteristics of that component, the one or more characteristics identified from a label for the component, any user input related to the component, and any elements included with the component.

4. The method of claim 3, wherein at least one element is included with the component, wherein the at least one element is selected from the group consisting of a communication node, register, and logic.

5. The method of claim 3, wherein the one or more characteristics identified from the label for the component are obtained from one or more prior designs of that component of the circuit design, from a specification for the component that may or may not have been designed yet, or from a default set being used to represent a generic component.

6. The method of claim 3, wherein the assigned boundary shape and layout area are based on a predicted shape based on the one or more characteristics of that component.

7. The method of claim 1, wherein the assigned boundary shape and layout area are a default assigned shape and area or a randomly assigned shape and area.

8. The method of claim 1, wherein the set of components of the circuit design comprises a subset of the circuit design containing fewer than all components of the circuit design.

9. The method of claim 1, wherein all the components of the circuit design are black-box components.

10. The method of claim 1, wherein the file indicating the set of components of the circuit design is a register-transfer-level (RTL) file.

11. The method of claim 1, wherein the file indicating the set of components of the circuit design is a netlist file.

12. The method of claim 1, further comprising:
converting the file indicating the set of components of the circuit design to a netlist.

13. The method of claim 1, wherein, for a black-box component of the set of components of the circuit design in the file, the black-box component comprises one or more connection nodes.

14. The method of claim 13, wherein, for the black-box component of the set of components having the one or more connection nodes, assigning at least one of the one or more connection nodes to a location at a boundary of that component after assigning the boundary shape and layout area for that component.

15. The method of claim 13, wherein, for the black-box component of the set of components having the one or more connection nodes, assigning at least one of the one or more connection nodes to a location within the layout area of that component after assigning the boundary shape and layout area for that component.

16. The method of claim 13, wherein the black-box component further comprises a register coupled to a connection node of the one or more connection nodes.

17. The method of claim 16, wherein the black-box component further comprises a logic gate coupled to the register.

18. The method of claim 1, wherein a component of the set of components has a dependency on an interface of a black-box component of the set of components.

19. The method of claim 1, wherein the physical design metric comprises timing, area, dynamic power/energy, static power/energy, placement density, routing congestion, or a combination thereof.

20. The method of claim 1, further comprising:
inserting, to a black-box component of the set of components of the circuit design in the file, one or more connection nodes.
